(19) United States
(12) Patent Application Publication
(10) Pub. No.: US 2010/0285272 A1
(43) Pub. Date: Nov. 11, 2010

(54) MULTI-LENGTH SCALE TEXTURED GLASS SUBSTRATES FOR ANTI-FINGERPRINTING

(76) Inventors: Shari Elizabeth Koval, Beaver Dams, NY (US); Mark Alejandro Quesada, Horseheads, NY (US); Wageesha Senaratne, Horseheads, NY (US)

Correspondence Address: CORNING INCORPORATED, SP-TI-3-1, CORNING, NY, 14831, US

(21) Appl. No.: 12/625,020

(22) Filed: Nov. 24, 2009

Related U.S. Application Data
(60) Provisional application No. 61/175,909, filed on May 6, 2009.

(51) Int. Cl. B32B 3/30; B05D 5/00; C23C 14/34

(52) U.S. Cl. 428/141; 427/166; 427/165; 204/192.1

(57) ABSTRACT

A glass substrate having at least one surface with engineered properties that include hydrophobicity, oleophobicity, anti-stick or adherence of particulate or liquid matter, durability, and transparency (i.e., haze<10%). The surface comprises a plurality of sets of topological features that together have a re-entrant geometry that prevents a decrease in contact angle and pinning of drops comprising at least one of water and sebaceous oils.

### CROSS REFERENCE TO RELATED APPLICATIONS

This application claims the benefit of U.S. Provisional Patent Application No. 61/175,909, filed May 6, 2009.

### BACKGROUND

Surfaces for touch screen applications are increasingly in demand. From both aesthetic and technological standpoints, touch screen surfaces which are resistant to the transfer or smudging of fingerprints are desired. For applications related to hand-held electronic devices, the general requirements for the user-interactive surface include high transmission, low haze, resistance to fingerprint transfer, robustness to repeated use, and non-toxicity. A fingerprint-resistant surface must be resistant to both water and oil transfer when touched by a finger of a user. The wetting characteristics of such a surface are such that the surface is both hydrophobic and oleophobic.

### SUMMARY

A glass substrate having at least one surface with engineered properties that include, but are not limited to, hydrophobicity (i.e., contact angle of water>90°), oleophobicity (i.e., contact angle of oil>90°), anti-stick or adherence of particulate or liquid matter found in fingerprints, durability, and transparency (i.e., haze<10%) is provided. The glass substrate has a plurality of topologies that provide hydrophobic and oleophobic properties.

Accordingly, one aspect of the disclosure is to provide a glass substrate having at least one surface that is hydrophobic and oleophobic. The surface comprises a plurality of sets of topological features, each of the sets having topological features of an average dimension that differs from the average dimensions of the topological features in the other sets. The sets of topological features together have a re-entrant geometry that prevents a decrease in contact angle of drops comprising at least one of water and sebaceous oils.

A second aspect of the disclosure is to provide a glass substrate having at least one surface that is hydrophobic and oleophobic. The surface has a plurality of sets of topological features disposed thereon. The sets of topological features comprise: a first level of topological features, the topological features in the first level having an average dimension of at least 1 μm; a second level of topological features, the topological features in the second level having an average dimension in a range from about 1 nm up to about 1 μm; and a third level of topological features. The topological features in the third level have an average dimension on a scale of the length of a covalent chemical bond.

A third aspect of the disclosure is to provide a method of making a glass substrate having at least one surface that is hydrophobic and oleophobic. The method comprises the steps of: providing a glass substrate having a surface and forming a plurality of sets of topological features on the surface. Each of the sets has topological features of an average dimension that differs from average dimensions of topological features in the other sets, wherein the sets of topological features together have a re-entrant geometry that prevents a decrease in contact angle of drops comprising at least one of water and sebaceous oils.

These and other aspects, advantages, and salient features will become apparent from the following detailed description, the accompanying drawings, and the appended claims.

### BRIEF DESCRIPTION OF THE DRAWINGS

FIG. 1a is a schematic representation of the Wenzel model of wetting behavior of a fluid droplet on a roughened solid surface;

FIG. 1b is a schematic representation of the Cassie-Baxter model of wetting behavior of a fluid droplet on a roughened solid surface;

FIG. 2 is a schematic representation of a glass substrate having multiple levels of topography;

FIG. 3 is an atomic force microscope image of surface topographic features having dimensions greater than 1 nm;

FIG. 4a is a cross-sectional view of the columnar structure of a sputtered SnO₂ film before etching;

FIG. 4b is a top view of the columnar structure of a sputtered SnO₂ film before etching;

FIG. 4c is a top view of the columnar structure of a sputtered SnO₂ film after etching with concentrated HCl for 5 minutes;

FIG. 5a is a top view of the columnar structure of a sputtered ZnO film before etching;

FIG. 5b is a top view of the columnar structure of a sputtered ZnO film after etching with 0.1 M HCl for 15 seconds;

FIG. 5c is a top view of the columnar structure of a sputtered ZnO film after etching with 0.1M HCl for 45 seconds;

FIG. 6a is a schematic representation of second topography voids that act as sites for pinning of fingerprints; and

FIG. 6b is a schematic representation of Teflon cusps formed to minimize pinning of fingerprints in second topography voids shown in FIG. 6a.

### DETAILED DESCRIPTION

In the following description, like reference characters designate like or corresponding parts throughout the several views shown in the figures. It is also understood that, unless otherwise specified, terms such as “top,” “bottom,” “outward,” “inward,” and the like are words of convenience and are not to be construed as limiting terms. In addition, whenever a group is described as comprising at least one of a group of elements and combinations thereof, it is understood that the group may comprise, consist essentially of, or consist of any number of those elements recited, either individually or in combination with each other. Similarly, whenever a group is described as consisting of at least one of a group of elements or combinations thereof, it is understood that the group may consist of any number of those elements recited, either individually or in combination with each other. Unless otherwise specified, a range of values, when recited, includes both the upper and lower limits of the range.

Referring to the drawings in general, it will be understood that the illustrations are for the purpose of describing particular embodiments and are not intended to limit the disclosure or appended claims thereto. The drawings are not necessarily to scale, and certain features and views of the drawings may be exaggerated in scale or in schematic in the interest of clarity and conciseness.

The primary characteristic of an article that resists or repels fingerprints is that the surface of the article must be non-wetting (i.e., the contact angle (CA) between a liquid drop and the surface is greater than 90°) with respect to the liquids that comprise such fingerprints. As used herein, the terms “anti-fingerprint” and “anti-fingerprinting” refer to the resistance of a surface to the transfer of fluids and other materials found in human fingerprints; the non-wetting properties of a surface with respect to such fluids and materials; the minimization, hiding, or obscuring of human fingerprints on a surface, and combinations thereof. Fingerprints comprise both sebaceous oils (e.g. secreted skin oils, fats, and waxes), debris of dead fat-producing cells, and aqueous components. An anti-fingerprinting surface must therefore be resistant to both water and oil transfer when touched by a finger of a user. The wetting characteristics of such a surface are such that that the surface is both hydrophobic (i.e., the contact angle (CA) between water and the glass substrate is greater than 90°) and oleophobic (i.e., the contact angle (CA) between oils and the glass substrate is greater than 90°).

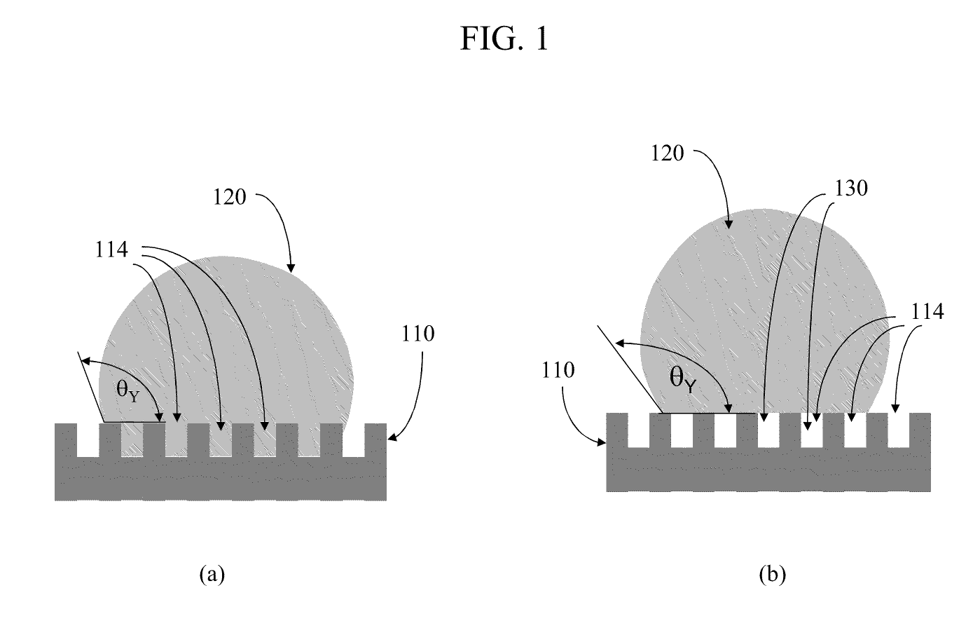

The presence of surface roughness (e.g., protrusions, depressions, grooves, pore, pits, voids, and the like) can alter the contact angle between a given fluid and a flat substrate, and is frequently referred to as the “lotus leaf” or “lotus” effect. As described by Quéré (Ann. Rev. Mater. Res. 2008, vol. 38, pp. 71-99), the wetting behavior of liquids on a roughened solid surface can be described by either the Wenzel (low contact angle) model or the Cassie-Baxter (high contact angle) model. In the Wenzel model, schematically shown in FIG. 1a, a fluid droplet 120 on a roughened solid surface 110 penetrates free space 114, which can include, but is not necessarily limited to, pits, holes, grooves, pores, voids and the like, on the roughened solid surface 110 and, in some instances, is “pinned” on roughened surface 112. The Wenzel model takes the increase in interface area of roughened solid surface 110 relative to a smooth surface (not shown) into account and predicts that when smooth surfaces are hydrophobic, roughening such surfaces will further increase their hydrophobicity. Conversely, when smooth surfaces are hydrophilic, the Wenzel model predicts that roughening such surfaces will further increase their hydrophilic behavior. In contrast to the Wenzel model, the Cassie-Baxter model (schematically shown in FIG. 1b) predicts that surface roughening always increases the contact angle θ_{Y} of fluid droplet 120 regardless of whether the smooth solid surface is hydrophilic or hydrophobic. The Cassie-Baxter model describes the case in which gas pockets 130 are formed in free space 114 of roughened solid surface 110 and trapped beneath fluid droplet 120 on a roughened solid surface 130, thus preventing a decrease in contact angle θ_{Y} and pinning of fluid droplet 120 on roughened solid surface 110. In addition to preventing pinning of fluid droplet 120, the presence of gas pockets 130 also increases contact angle θ_{Y} of fluid droplet 120. Pressure, such as that applied by a human finger, applied to fluid droplet 120 can cause fluid droplet 120 to penetrate free space 114 and become pinned on roughened solid surface—i.e., fluid droplet 120 transitions from the Cassie-Baxter state (FIG. 1b) to the Wenzel state (FIG. 1a). An anti-fingerprinting surface should, when in contact with a given fluid, provide a lotus leaf effect and maintain droplets in the Cassie-Baxter state, in which gas pockets are trapped beneath fluid droplets on a roughened solid surface and pinning of the fluid droplets is avoided and, to some degree, prevent or retard a decrease in contact angle θ_{Y} and transition to the Wenzel state when pressure is applied to the fluid droplets.

The hyrodphobicity and oleophobicity of surfaces are also related to the surface energy γ_{SV} of the solid substrate. The contact angle θ_{Y} of a surface with a fluid droplet is defined by the equation

$$Cos {θ}_{Y} = \frac{{γ}_{SV} - {γ}_{SL}}{{γ}_{LV}}$$

where θ_{Y} is the contact angle for a flat surface (also known as Young's contact angle), γ_{SV} is the surface energy of the solid, γ_{SL} is the interface energy between the liquid and solid, and γ_{LV} is the liquid surface tension. In order for θ_{Y}>90°, the term cos θ_{Y} must be negative, thereby constraining the surface energy γ_{SV} to values less than γ_{SL}. The interface energy between the liquid and solid γ_{SL} is typically not known and the contact angle θ_{Y} is usually increased to greater than 90° (i.e., cos θ_{Y}<0) in order to minimize the surface energy γ_{SV} of the solid and achieve hydrophobicity and/or oleophobicity. For example, traditional non-wetting unroughened or smooth surfaces, including fluorinated materials such as Teflon™ (polytetrafluoroethane), have surface energies as low as 18 dynes/cm. A Teflon surface is not oleophobic, as routinely studied oils such as oleic acid (γ_{LV}˜32 dyne/cm) exhibit contact angles on Teflon of about 80°.

Anti-fingerprinting surfaces that are hydrophobic and oleophobic can be achieved by creating rough surfaces having low surface energy. Accordingly, a glass article or substrate (unless otherwise specified, the terms “glass article” and “glass substrate” are equivalent terms and are used interchangeably herein) having at least one surface with engineered properties that include, but are not limited to, hydrophobicity and oleophobicity is provided. Other properties, including anti-fingerprinting, anti-stick or anti-adherence of particulate matter, durability, transparency (e.g., haze<10%), and the like are also provided in various embodiments. These attributes are achieved by providing the surface of the substrate with a plurality of different sets or levels of topological features that include, but are not limited to, bumps, protrusions, depressions, pits, voids, and the like. The topological features in one set or level of topological features has an average dimension that differs from the average dimensions of the topological features in the other sets or levels. The sets of topological features together form a re-entrant geometry that prevents a decrease in contact angle θ_{Y} and pinning of drops comprising at least one of water and sebaceous oils.

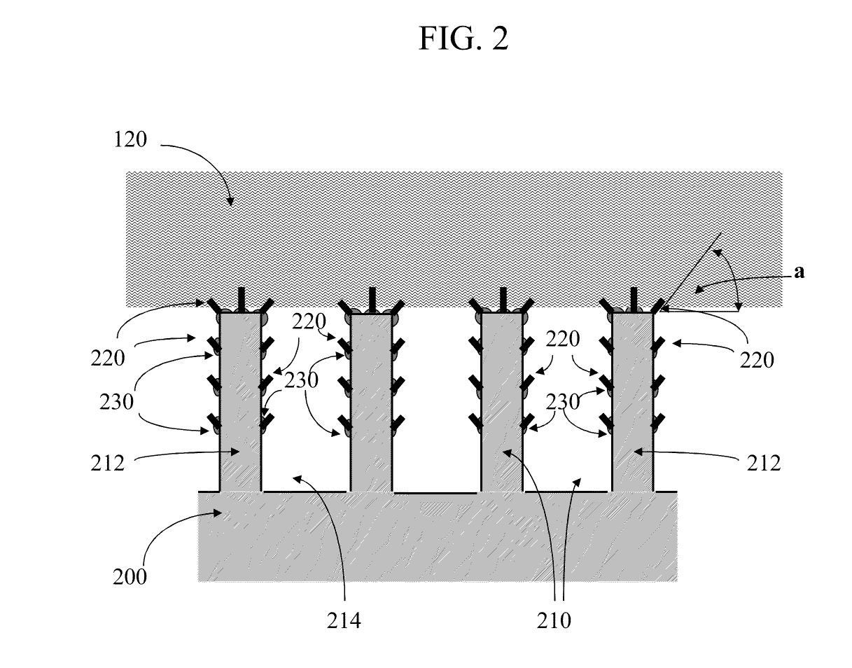

A cross sectional view of an example of a glass substrate surface having multiple sets of topographies is schematically shown in FIG. 2. The surface structure shown in FIG. 2 resists material a decrease in contact angle θ_{Y} and penetration or “pinning” of liquid drops in surface voids, thus providing hydrophobic, oleophobic, anti-adhesive, and anti-fingerprinting properties. Furthermore, the surface structure shown in FIG. 2 serves as a non-limiting example of the type of surface that is capable of providing some measure of the lotus leaf effect. Hydrophobic/oleophobic surface 200 includes a first topography 210, a second topography 220, and a third topography 230.

First topography 210 comprises a plurality of protrusions 212 and depressions 214. First topography 210 has the largest length scale of the topographies shown in FIG. 2, in which the topological features (here, protrusions 212 and depressions 214) have a first average dimension which, in some embodiments, is greater than or equal to 1 μm. In one embodiment, the average dimension of the topological features of first topography 210 is in a range from about 1 μm up to about 50 μm. In another embodiment, the average dimension of the topological features of first topography 210 is in a range from about 1 μm up to about 10 μm. First topography 210, in one embodiment, can comprise any etchable inorganic oxide such as, but not limited to, SnO₂, ZnO, ceria, alumina, zirconia, or the like.

A second or intermediate length scale topography 220 is superimposed on first topography 210. Second topography 220 provides a reentrant geometry that prevents or slows the transition of fluid droplets 120 on a roughened surface from a Cassie-Baxter state (FIG. 1b) to a Wenzel state (FIG. 1a). In a Cassie-Baxter state, fluid drop 120 rests atop protrusions 212 that comprise first topography 210. Features of second topography 220 protrude from first topography 210 at an angle a from the plane of glass substrate 200 and at least partially block entry of fluid drop 120 into free space, formed by depressions 214, between protrusions 212 and thus prevent or slow the transition of the surface of glass substrate 200 to the Wenzel state (FIG. 1a).

As seen in FIG. 2, second topography 220 can comprise protrusions on the surfaces on the larger protrusions of first topography 210. The average dimension of topological features in second topography 220 is less than the average dimension of first topography 210 and, in some embodiments, is in a range from about 1 nm up to about 1 μm. In one embodiment, second topography 220 comprises metals or any etchable inorganic oxide such as, but not limited to, SnO₂, ZnO, ceria, alumina, zirconia, or the like.

A third or smallest length scale topography 230 has topological features on the scale of a chemical bond (in a range from about 0.7 Angstrom up to about 3 Angstroms (70-300 pm). The third topography 230 is wax-like and has a low surface energy derivatization. In some embodiments, third topography 230 is a coating that covers at least a portion of the surface of first and second topography 210, 220 and comprises a low surface energy polymer or an oligomer, such as, but not limited to, Teflon™ or other commercially available fluoropolymers or fluorosilanes such as, but are not limited to Dow Corning 2604, 2624, 2634, DK Optool DSX, Shintesu OPTRON, heptadecafluoro silane (Gelest), FluoroSyl (Cytonix), and the like. To prevent pinning of droplet 120 in voids within second topography 210 upon application of pressure (e.g. pressure applied by a finger), third topography 230 is tailored to form cusps 230 at re-entrant voids or trench walls to minimize pinning, thus providing an additional effective re-entry impeding geometry.

In some embodiments, the glass substrate is a planar or three dimensional sheet having two major surfaces. At least one major surface of the glass substrate has a plurality of different sets or levels of topological features as described herein. In some embodiments both major surfaces of the substrate have a plurality of levels of topographical features. In other embodiments, a single major surface of the glass substrate has such features.

A method of making a glass substrate having a surface that is hydrophobic and oleophobic is also provided. The method comprises the steps of providing a glass substrate having a surface; and forming a plurality of sets of topological features on the surface. Each of the sets has topological features of an average dimension that differs from average dimensions of topological features in the other sets. Together the sets of topological features together have a re-entrant geometry that prevents a decrease in contact angle θ_{Y} and pinning of drops comprising at least one of water and sebaceous oils.

In various embodiments, the plurality of sets of topological features comprise at least one of first topography 210, second topography 220, and third topography 230, previously described hereinabove.

In one embodiment, first topography 210 can be formed by sandblasting the surface of the glass substrate 200. In one non-limiting example, the surface of the glass substrate 200 is sandblasted with 50 μm alumina grit for differing amounts of time to achieve desired roughness parameters. The sandblasted surface is then coated with inorganic oxide via deposition methods described herein to achieve first topography 210.

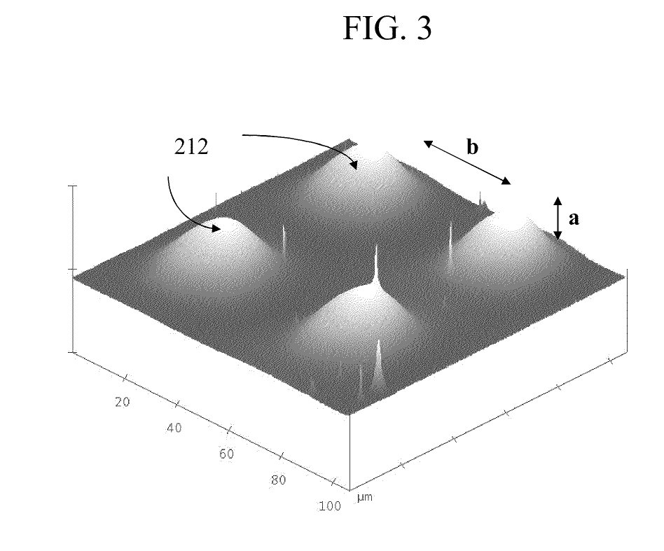

In another embodiment, first topography 210 is formed by depositing a thin oxide film through a shadow mask onto the surface of glass substrate 200 using physical or chemical vapor deposition methods known in the art. In one embodiment, a shadow mask is placed on a surface of the glass substrate. ZnO is then sputtered onto the glass substrate through a mask, resulting in a first topography 210 that mimics the mask features. FIG. 3, which is an atomic force microscope (AFM) image of the sputtered ZnO surface, shows features of first topography 210. Such features include 25 nm-diameter “bumps” 212 having a height a of approximately 50 nm and a pitch or spacing b of about 55 nm.

Second topography 220 can be formed using those physical (e.g., sputtering, evaporation, laser ablation, or the like) or chemical vapor deposition methods (e.g., CVD, plasma assisted or enhanced CVD, or the like) known in the art. In one embodiment, second topography 220 is achieved by etching a sputtered metal oxide thin film or by anodizing an evaporated metal film. Sputtering parameters (e.g., sputtering pressure and substrate temperature) can be correlated with etching behavior to produce a desired topography. The modified Thornton model of O. Kluth, et al. (“Modified Thornton Model for Magnetron Sputtered Zinc Oxide: Film Structure and Etching Behavior,” Thin Solid Films, 2003, vol. 442, pp. 80-85), the contents of which are incorporated by reference herein in their entirety, describes the correlation between sputter parameters (sputter pressure and glass substrate temperature), structural film properties, and etching behavior of RF sputtered films on glass substrates. Appropriate adjustment of sputtering conditions is used to select and form a sputtered columnar or granular morphology that is subsequently etched.

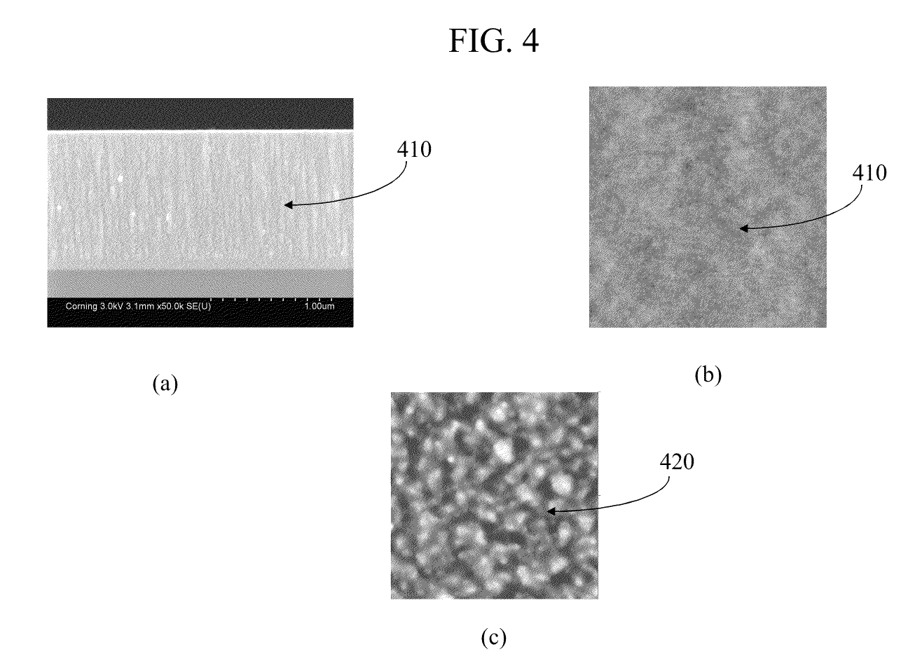

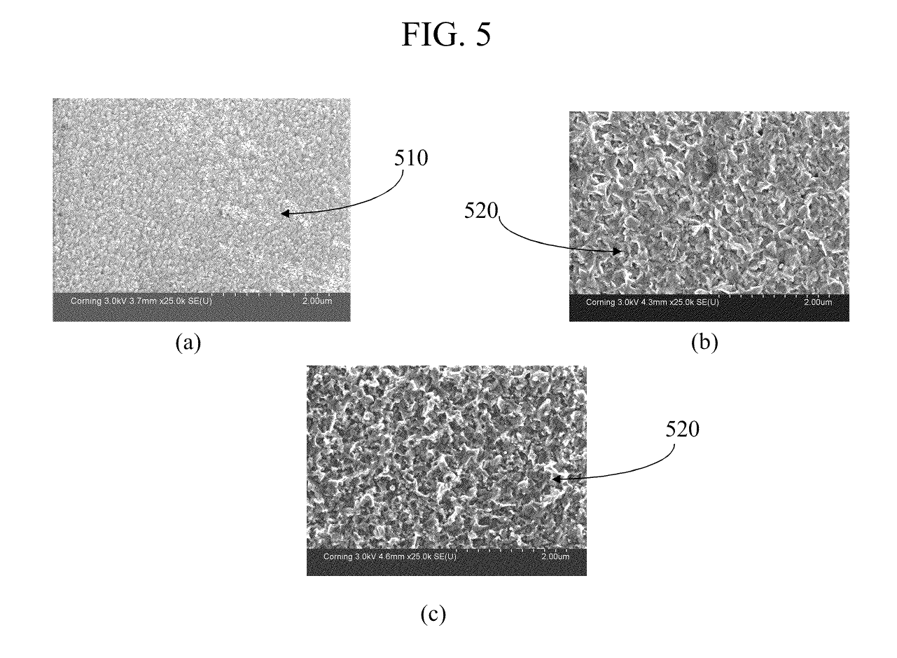

FIGS. 4a-c and 5a-c are scanning electron microscopy (SEM) images showing two examples of how 10-100 nm surface features of second topography 220 are formed by etching. The individual surface features shown in FIGS. 4 and 5 have dimensions of between about 10 and 500 nm. FIGS. 4a-c show the effect of strong etching using concentrated HCl for 5 minutes on a sputtered SnO₂ film having a columnar structure. FIG. 4 includes SEM images of side or cross-sectional (FIG. 4a) and top (FIG. 4b) views of the columnar structure 410 of the SnO₂ film before etching. A microscopic image of a top view of the SnO₂ film after etching to achieve the desired level of roughness and produce second topography 420 is shown in FIG. 4c.

FIGS. 5a-c show the effect of mild etching upon sputtered ZnO films having a columnar structure similar to that shown for SnO₂ in FIG. 4a. FIG. 5a is a top view of the columnar structure 510 of the ZnO film before etching and FIGS. 5b and 5c are top views of the columnar structure of the sputtered ZnO film after etching for 15 seconds and 45 seconds, respectively, with 0.1 M HCl to produce second topography 520. The roughness of the ZnO films increased with increasing etch time.

The third topography comprises a low surface energy polymer or an oligomer, such as, but not limited to, fluoropolymers or fluorosilanes previously described herein. The third topography is formed following formation of the first and second topography layers. The oligomers or polymer comprising the third topography are deposited onto the surface of the glass substrate 200 by sputtering, spray coating, spin-coating, dip-coating, or the like.

Teflon adheres well to alkali aluminosilicate glass surfaces, whether or not those surfaces are ion exchanged, and is easy to sputter. Teflon deposition rates are as high as about 7 nm/minute for argon sputtering (50 W, 1-5 millitorr conditions). Sputtered Teflon exhibits little change in hydrophobicity when treated with O₂ plasma (5-15 min, 200 W); the contact angle for water did not exceed about 100° contact angle. However, O₂ plasma-treatment of sputtered Teflon increases the oleophobicity threefold from 20° to 60°.

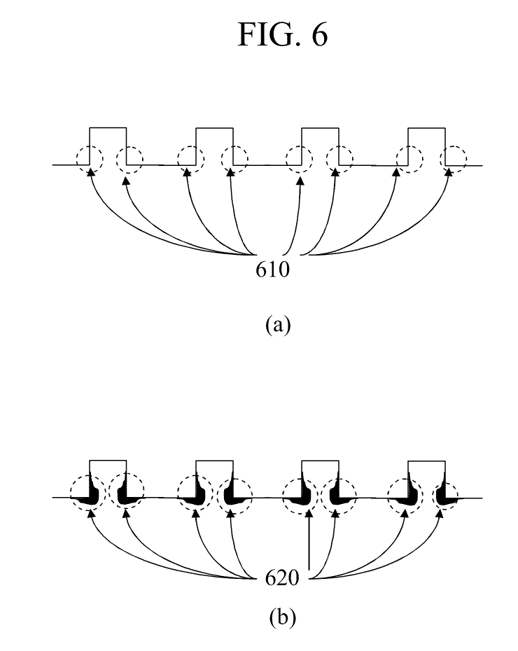

A non-limiting example of a third topography comprising a low surface energy surface of sputtered Teflon is schematically shown in FIGS. 6a and b. FIGS. 6a-b also schematically shows how the re-entrant impeding geometry and pinning of the fingerprint components are mitigated. To prevent adsorbed components of fingerprints from dispersing into and being pinned in voids 610 in the second topography (FIG. 6a) upon application of finger pressure, deposition conditions for sputtering Teflon are tailored to form cusps 620 (FIG. 6b) at re-entrant void (trench) walls 710 to minimize pinning in the voids or trench walls, thus providing an inexpensive effective re-entry impeding geometry. This is achieved by using sputtering conditions known in the art under which the mean free path during deposition is small. In addition, the surface of the glass substrate is cooled to reduce surface migration.

The combination of different surface topographies as described herein provides, in one embodiment, the surface of the glass substrate with enhanced durability when rubbed with a fabric or other instrument such as, for example, a human finger. Coating durability (also referred to as Crock Resistance) refers to the ability of the coated glass sample to withstand repeated rubbing with a cloth. The Crock Resistance test is meant to mimic the physical contact between garments or fabrics with a touch screen device and to determine the durability of the coating after such treatment.

A Crockmeter is a standard instrument that is used to determine the Crock resistance of a surface subjected to such rubbing. The Crockmeter subjects a glass slide to direct contact with a rubbing tip or finger mounted on the end of a weighted arm. The standard finger supplied with the Crockmeter is a 15 mm diameter solid acrylic rod. A clean piece of standard crocking cloth is mounted to this acrylic finger. The finger then rests on the sample with a pressure of 900 g and the arm is moved repeatedly back and forth across the sample in an attempt to observe a change in the durability/crock resistance. The Crockmeter used in the tests described herein is a motorized model that provides a uniform stroke rate of 60 revolutions per minute. The Crockmeter test is described in ASTM test procedure F1319-94, entitled “Standard Test Method for Determination of Abrasion and Smudge Resistance of Images Produced from Business Copy Products.”

Crock Resistance or durability of the coatings and surfaces described herein is determined by optical (e.g., haze or transmittance) or chemical (e.g., water and/or oil contact angle) measurements after a specified number of wipes, where a wipe is defined as two strokes or one cycle, of the rubbing tip or finger. For example, the durability of a surface can be determined after 100, 1,000, 5,000, or 10,000 wipes. In one embodiment, the surface of the glass substrate having the plurality of topographies described herein is hydrophobic, oleophobic, or both (i.e., the contact angle of water and/or oleic acid on the surface is greater than 90°) after at least 100 wipes as defined by ASTM test procedure F1319-94. The glass substrate described herein also retains a low level of haze after such repeated wiping. In one embodiment, the glass substrate has a haze of less than 10% after at least 100 wipes as defined by ASTM test procedure F1319-94.

The contact angle (θ_{Y}), previously described herein, is frequently used as a metric for assessing anti-fingerprinting oleophobic and hydrophobic properties. As previously discussed, the contact angle is a measure of the degree of wetting between hydrophilic and/or oleophilic fingerprint components and the engineered surface of the glass substrate. The less wetting (i.e., the higher the contact angle), the less adhesion to the surface. For anti-fingerprinting and anti-adhesive properties, the contact angle, in one embodiment, is greater than 90° C. for both oleophilic and hydrophilic materials.

In one non-limiting example, water (hydrophilic) and oleic acid (oleophiolilic) contact angles were measured on alkali aluminosilicate glass samples having surfaces with the topographies described herein. Each glass surface was prepared for ZnO sputtering by first subjecting each glass surface to plasma treatment with O₂ plasma at 200 Watts for 5 minutes. ZnO was then deposited on the glass surface by sputtering ZnO targets for 60 minutes using 50 Watts RF power in a 1 millitorr argon chamber. The samples were etched for either 15, 30, 45, or 90 seconds in 0.05 M HCl, and the contact angles for water and oleic acid were then measured. The samples were then dip-coated in a fluorosilane solution comprising EZ-Clean™ (Dow Corning DC2604), followed by another contact angle measurement. Water and oleic contact angles for each sample are listed in Table 1. As seen in Table 1, hydrophilic contact angles measured before coating the textured samples with EZ-clean (“Without EZ-clean” in Table 1) are low, ranging from about 15° (sample D) to slightly less than 30° (sample 1). Following dip coating in EZ clean (“With EZ-clean” in Table 1), the hydrophilic contact angle for each sample was substantially increased to values that are greater than the 90° threshold for hydrophobicity, and in a range from about 131° up to 139°. Similarly, the contact angle for oleic acid measured for each sample exceeded the threshold for oleophobic behavior, and ranged from about 93° up to about 96. The glass surfaces that had been provided with the surfaces having multiple topographies (including the third topography provided by EZ-clean) as described herein exhibit both hydrophobic and oleophobic behavior, as evidenced by the results of the contact angle measurements presented in Table 1.

TABLE 1
Contact angles of water and oleic acid, expressed in degrees,
on alkali aluminosilicate glass surfaces sputtered with ZnO.

| | Etch time (seconds) | | | | | | | |
|---|---|---|---|---|---|---|---|---|
| Sam- | 15 | | 30 | | 45 | | 90 | |
| ple | Water | Oil | Water | Oil | Water | Oil | Water | Oil |
| With- | | | | | | | | |
| out | | | | | | | | |
| EZ- | | | | | | | | |
| clean | | | | | | | | |
| A | 29.8° | — | — | — | — | — | — | — |
| B | — | — | 25.9° | — | — | — | — | — |
| C | — | — | — | — | 26.5° | — | — | — |
| D | — | — | — | — | — | — | 15.2° | — |
| With | | | | | | | | |
| EZ- | | | | | | | | |
| clean | | | | | | | | |
| A | 133° | 93.4° | — | — | — | — | — | — |
| B | — | — | 131.5° | 91.1° | — | — | — | — |
| C | — | — | — | — | 139° | 96.1° | — | — |
| D | — | — | — | — | — | — | 134.4° | 91.2° |

In one embodiment, the glass article comprises, consists essentially of, or consists of a soda lime glass. In another embodiment, the glass article comprises, consists essentially of, or consists of any glass that can be down-drawn, such as, but not limited to, an alkali aluminosilicate glass. In one embodiment, the alkali aluminosilicate glass comprises, consists essentially of, or consists of: 60-72 mol % SiO₂; 9-16 mol % Al₂O₃; 5-12 mol % B₂O₃; 8-16 mol % Na₂O; and 0-4 mol % K₂O, wherein the ratio

$$\frac{{Al}_{2} {O}_{3} ( mol \% ) + {B}_{2} {O}_{3} ( mol \% )}{\sum alkali metal modifiers ( mol \% )} > 1 ,$$

where the alkali metal modifiers are alkali metal oxides. In another embodiment, the alkali aluminosilicate glass comprises, consists essentially of, or consists of: 61-75 mol % SiO₂; 7-15 mol % Al₂O₃; 0-12 mol % B₂O₃; 9-21 mol % Na₂O; 0-4 mol % K₂O; 0-7 mol % MgO; and 0-3 mol % CaO. In yet another embodiment, the alkali aluminosilicate glass comprises, consists essentially of, or consists of: 60-70 mol % SiO₂; 6-14 mol % Al₂O₃; 0-15 mol % B₂O₃; 0-15 mol % Li₂O; 0-20 mol % Na₂O; 0-10 mol % K₂O; 0-8 mol % MgO; 0-10 mol % CaO; 0-5 mol % ZrO₂; 0-1 mol % SnO₂; 0-1 mol % CeO₂; less than 50 ppm As₂O₃; and less than 50 ppm Sb₂O₃; wherein 12 mol %≦Li₂O+Na₂O+K₂O≦20 mol % and 0 mol % MgO+CaO≦10 mol %. In still another embodiment, the alkali aluminosilicate glass comprises, consists essentially of, or consists of: 64-68 mol % SiO₂; 12-16 mol % Na₂O; 8-12 mol % Al₂O₃; 0-3 mol % B₂O₃; 2-5 mol % K₂O; 4-6 mol % MgO; and 0-5 mol % CaO, wherein: 66 mol %≦SiO₂+B₂O₃+CaO≦69 mol %; Na₂O+K₂O+B₂O₃+MgO+CaO+SrO>10 mol %; 5 mol %≦MgO+CaO+SrO≦8 mol %; (Na₂O+B₂O₃)—Al₂O₃≦2 mol %; 2 mol % Na₂O—Al₂O₃≦6 mol %; and 4 mol %≦(Na₂O+K₂O)—Al₂O₃≦10 mol %. In a third embodiment, the alkali aluminosilicate glass comprises, consists essentially of, or consists of: 50-80 wt % SiO₂; 2-20 wt % Al₂O₃; 0-15 wt % B₂O₃; 1-20 wt % Na₂O; 0-10 wt % Li₂O; 0-10 wt % K₂O; and 0-5 wt % (MgO+CaO+SrO+BaO); 0-3 wt % (SrO+BaO); and 0-5 wt % (ZrO₂+TiO₂), wherein 0≦(Li₂O+K₂O)/Na₂O≦0.5.

In one particular embodiment, the alkali aluminosilicate glass has the composition: 66.7 mol % SiO₂; 10.5 mol % Al₂O₃; 0.64 mol % B₂O₃; 13.8 mol % Na₂O; 2.06 mol % K₂O; 5.50 mol % MgO; 0.46 mol % CaO; 0.01 mol % ZrO₂; 0.34 mol % As₂O₃; and 0.007 mol % Fe₂O₃. In another particular embodiment, the alkali aluminosilicate glass has the composition: 66.4 mol % SiO₂; 10.3 mol % Al₂O₃; 0.60 mol % B₂O₃; 4.0 mol % Na₂O; 2.10 mol % K₂O; 5.76 mol % MgO; 0.58 mol % CaO; 0.01 mol % ZrO₂; 0.21 mol % SnO₂; and 0.007 mol % Fe₂O₃.

The alkali aluminosilicate glass is, in some embodiments, substantially free of lithium, whereas in other embodiments, the alkali aluminosilicate glass is substantially free of at least one of arsenic, antimony, and barium. In some embodiments, the glass article is down-drawn, using those methods known in the art such as, but not limited to fusion-drawing, slot-drawing, re-drawing, and the like.

Non-limiting examples of such alkali aluminosilicate glasses are described in U.S. patent application Ser. No. 11/888,213, by Adam J. Ellison et al., entitled “Down-Drawable, Chemically Strengthened Glass for Cover Plate,” filed on Jul. 31, 2007, which claims priority from U.S. Provisional Patent Application 60/930,808, filed on May 22, 2007, and having the same title; U.S. patent application Ser. No. 12/277,573, by Matthew J. Dejneka et al., entitled “Glasses Having Improved Toughness and Scratch Resistance,” filed on Nov. 25, 2008, which claims priority from U.S. Provisional Patent Application 61/004,677, filed on Nov. 29, 2007, and having the same title; U.S. patent application Ser. No. 12/392,577, by Matthew J. Dejneka et al., entitled “Fining Agents for Silicate Glasses,” filed Feb. 25, 2009, which claims priority from U.S. Provisional Patent Application No. 61/067,130, filed Feb. 26, 2008, and having the same title; U.S. patent application Ser. No. 12/393,241 by Matthew J. Dejneka et al., entitled “Ion-Exchanged, Fast Cooled Glasses,” filed Feb. 26, 2009, which claims priority from U.S. Provisional Patent Application No. 61/067,732, filed Feb. 29, 2008. and having the same title; U.S. patent application Ser. No. 12/537,393, by Kristen L. Barefoot et al., entitled “Strengthened Glass Articles and Methods of Making,” filed Aug. 7, 2009, which claims priority from U.S. Provisional Patent Application No. 61/087,324, entitled “Chemically Tempered Cover Glass,” filed Aug. 8, 2008; U.S. Provisional Patent Application No. 61/235,767, by Kristen L. Barefoot et al., entitled “Crack and Scratch Resistant Glass and Enclosures Made Therefrom,” filed Aug. 21, 2009; and U.S. Provisional Patent Application No. 61/235,762, by Matthew J. Dejneka et al., entitled “Zircon Compatible Glasses for Down Draw,” filed Aug. 21, 2009; the contents of which are incorporated herein by reference in their entirety.

The glass article or substrate is chemically or thermally strengthened before forming the roughened glass substrate surface described herein. In one embodiment, the glass article is strengthened either before or after being cut or separated from a “mother sheet” of glass. The strengthened glass article has strengthened surface layers extending from a first surface and a second surface to a depth of layer below each surface. The strengthened surface layers are under compressive stress, whereas a central region of the glass article is under tension, or tensile stress, so as to balance forces within the glass. In thermal strengthening (also referred to herein as “thermal tempering”), the glass article is heated up to a temperature that is greater than the strain point of the glass but below the softening point of the glass and rapidly cooled to a temperature below the strain point to create strengthened layers at the surfaces of the glass. In another embodiment, the glass article can be strengthened chemically by a process known as ion exchange. In this process, ions in the surface layer of the glass are replaced by—or exchanged with—larger ions having the same valence or oxidation state. In those embodiments in which the glass article comprises, consists essentially of, or consists of an alkali aluminosilicate glass, ions in the surface layer of the glass and the larger ions are monovalent alkali metal cations, such as Li⁺ (when present in the glass), Na⁺, Rb⁺, and Cs⁺. Alternatively, monovalent cations in the surface layer may be replaced with monovalent cations other than alkali metal cations, such as Ag⁺ or the like.

Ion exchange processes typically comprise immersing a glass article in a molten salt bath containing the larger ions to be exchanged with the smaller ions in the glass. It will be appreciated by those skilled in the art that parameters for the ion exchange process including, but not limited to, bath composition and temperature, immersion time, the number of immersions of the glass in a salt bath (or baths), use of multiple salt baths, additional steps such as annealing, washing, and the like, are generally determined by the composition of the glass and the desired depth of layer and compressive stress of the glass to be achieved by the strengthening operation. By way of example, ion exchange of alkali metal-containing glasses may be achieved by immersion in at least one molten salt bath containing a salt such as, but not limited to, nitrates, sulfates, and chlorides of the larger alkali metal ion. The temperature of the molten salt bath typically is in a range from about 380° C. up to about 450° C., while immersion times range from about 15 minutes up to about 16 hours. However, temperatures and immersion times different from those described above may also be used. Such ion exchange treatments typically result in strengthened alkali aluminosilicate glasses having depths of layer ranging from about 10 μm up to at least 50 μm with a compressive stress ranging from about 200 MPa up to about 800 MPa, and a central tension of less than about 100 MPa.

Non-limiting examples of ion exchange processes are provided in the U.S. patent applications and provisional patent applications that have been previously referenced hereinabove. Additional non-limiting examples of ion exchange processes in which glass is immersed in multiple ion exchange baths, with washing and/or annealing steps between immersions, are described in U.S. patent application Ser. No. 12/500,650, by Douglas C. Allan et al., entitled “Glass with Compressive Surface for Consumer Applications,” filed Jul. 10, 2009, which claims priority from U.S. Provisional Patent Application No. 61/079,995, filed Jul. 11, 2008, and having the same title, in which glass is strengthened by immersion in multiple, successive, ion exchange treatments in salt baths of different concentrations; and U.S. patent application Ser. No. 12/510,599, by Christopher M. Lee et al., entitled “Dual Stage Ion Exchange for Chemical Strengthening of Glass,” filed Jul. 28, 2009, which claims priority from U.S. Provisional Patent Application No. 61/084,398 filed Jul. 29, 2008, and having the same title, in which glass is strengthened by ion exchange in a first bath is diluted with an effluent ion, followed by immersion in a second bath having a smaller effluent ion concentration than the first bath. The contents of U.S. patent application Ser. Nos. 12/500,650 and 12/510,599 are incorporated herein by reference in their entirety.

The glass substrate described herein can be used as a protective cover for display and touch applications, such as, but not limited to, portable communication and entertainment devices such as telephones, music players, video players, or the like; and as display screens for information-related terminals (IT) (e.g., portable or laptop computers) devices; as well as in other applications.

While typical embodiments have been set forth for the purpose of illustration, the foregoing description should not be deemed to be a limitation on the scope of the disclosure or appended claims. Accordingly, various modifications, adaptations, and alternatives may occur to one skilled in the art without departing from the spirit and scope of the present disclosure or appended claims.

1. A glass substrate having at least one surface that is hydrophobic and oleophobic, the at least one surface comprising a plurality of sets of topological features, each of the sets having topological features of an average dimension that differs from average dimensions of topological features in the other sets, wherein the sets of topological features together have a re-entrant geometry that prevents a decrease in contact angle of drops comprising at least one of water and sebaceous oils.

2. The glass substrate according to claim 1, wherein the glass substrate comprises one of an alkali aluminosilicate glass and a soda lime glass.

3. The glass substrate according to claim 2, wherein the alkali aluminosilicate glass is strengthened by ion exchange.

4. The glass substrate according to claim 2, wherein the alkali aluminosilicate glass comprises: 60-72 mol % SiO₂; 9-16 mol % Al₂O₃; 5-12 mol % B₂O₃; 8-16 mol % Na₂O; and 0-4 mol % K₂O, wherein the ratio
$$\frac{{Al}_{2} {O}_{3} ( mol \% ) + {B}_{2} {O}_{3} ( mol \% )}{\sum alkali metal modifiers ( mol \% )} > 1 ,$$
where the alkali metal modifiers are alkali metal oxides.

5. The glass substrate according to claim 2, wherein the alkali aluminosilicate glass comprises: 61-75 mol % SiO₂; 7-15 mol % Al₂O₃; 0-12 mol % B₂O₃; 9-21 mol % Na₂O; 0-4 mol % K₂O; 0-7 mol % MgO; and 0-3 mol % CaO.

6. The glass substrate according to claim 2, wherein the alkali aluminosilicate glass comprises: 60-70 mol % SiO₂; 6-14 mol % Al₂O₃; 0-15 mol % B₂O₃; 0-15 mol % Li₂O; 0-20 mol % Na₂O; 0-10 mol % K₂O; 0-8 mol % MgO; 0-10 mol % CaO; 0-5 mol % ZrO₂; 0-1 mol % SnO₂; 0-1 mol % CeO₂; less than 50 ppm As₂O₃; and less than 50 ppm Sb₂O₃; wherein 12 mol %≦Li₂O+Na₂O+K₂O≦20 mol % and 0 mol % MgO+CaO≦10 mol %.

7. The glass substrate according to claim 1, wherein the plurality of sets of topological features comprises at least one of:
a. a first level of topological features, the topological features in the first level having an average dimension of at least 1 μm;
b. a second level of topological features, the topological features in the second level having an average dimension in a range from about 1 nm up to about 1 μm; and
c. a third level of topological features, the topological features in the third level having an average dimension of a scale of the length of a covalent chemical bond.

8. The glass substrate according to claim 7, wherein the first level of topological features comprises a sandblasted portion of the surface.

9. The glass substrate according to claim 7, wherein the first level of topological features comprises a patterned film deposited on the surface, the patterned film comprising an inorganic oxide.

10. The glass substrate according to claim 9, wherein the inorganic oxide comprises at least one of tin oxide, zinc oxide, ceria, alumina, zirconia, and combinations thereof.

11. The glass substrate according to claim 7, wherein the average dimension of the topological features in the first level is in a range from about 1 μm up to about 50 μm.

12. The glass substrate according to claim 7, wherein the second level of topological features comprises an etched film, the etched film comprising an inorganic oxide.

13. The glass substrate according to claim 12, wherein the inorganic oxide comprises at least one of tin oxide, zinc oxide, ceria, alumina, zirconia, and combinations thereof.

14. The glass substrate according to claim 7, wherein the third level of topological features comprises at least one of a fluoropolymer and a fluorosilane.

15. The glass substrate according to claim 1, wherein the surface of the glass substrate, after 100 wipes, has a water contact angle of greater than 90°.

16. The glass substrate according to claim 1, wherein the surface of the glass substrate, after 100 wipes, has a oleic acid contact angle of greater than 90°.

17. The glass substrate according to claim 1, wherein the glass substrate has a haze of less than 10% after 100 wipes.

18. The glass substrate according to claim 1, wherein the glass substrate has anti-fingerprint properties.

19. The glass substrate according to claim 1, wherein the glass substrate is one of a touch screen and a protective cover glass for at least one of a hand held electronic device, an information-related terminal, and a touch sensor device.

20. A glass substrate having at least one surface that is hydrophobic and oleophobic, the surface having a plurality of sets of topological features disposed thereon, the sets of topological features comprising:
a. a first level of topological features, the topological features in the first level having an average dimension of at least 1 μm;
b. a second level of topological features, the topological features in the second level having an average dimension in a range from about 1 nm up to about 1 μm; and
c. a third level of topological features, the topological features in the third level having an average dimension on a scale of the length of a covalent chemical bond.

21. A method of making a glass substrate having a surface that is hydrophobic and oleophobic, the method comprising the steps of:
a. providing a glass substrate having at least one surface; and
b. forming a plurality of sets of topological features on the surface, each of the sets having topological features of an average dimension that differs from average dimensions of topological features in the other sets, wherein the sets of topological features together have a re-entrant geometry that prevents a decrease in contact angle of drops comprising at least one of water and sebaceous oils.

22. The method according to claim 21, wherein the step of forming the plurality of sets of topological features on the surface comprises forming a first surface topology on the surface, the first surface topology including topological features having a first average dimension of at least about 1 μm.

23. The method according to claim 22, wherein the step of forming the first surface topology on the surface comprises depositing a metal oxide on the surface by one of physical vapor deposition and chemical vapor deposition.

24. The method according to claim 22, wherein the step of forming the first topology on the surface of the glass substrate comprises sandblasting the surface of the glass substrate.

25. The method according to claim 22, wherein the step of forming the plurality of sets of topological features on the surface further comprises forming a second surface topology on the surface, the second surface topology including topological features having second average dimension that is less than the first average dimension.

26. The method according to claim 25, wherein the step of forming the second surface topology comprises depositing at least one of a metal oxide on the surface by one of physical vapor deposition and chemical vapor deposition.

27. The method according to claim 25, wherein the second average dimension is in a range from about 1 nm up to about 1 μm.

28. The method according to claim 22, wherein the step of forming the plurality of sets of topological features on the surface further comprises forming a third surface topology on the surface, the third surface topology including topological features having third average dimension on a scale of the length of a covalent chemical bond.

29. The method according to claim 28, wherein the step of forming the third surface topology on the surface comprises depositing at least one of a fluoropolymer and a fluorosilane on the surface by one of sputtering, spray coating, spin coating, and dip-coating.
